(19) United States
(12) Patent Application Publication
(10) Pub. No.: US 2026/0343829 A1
(43) Pub. Date: Oct. 29, 2026

(54) COOLING DEVICE

(71) Applicant: MITSUBISHI HEAVY INDUSTRIES, LTD., Tokyo (JP)

(72) Inventors: Nobuhide Hara, Tokyo (JP); Yuichi Otani, Tokyo (JP)

(73) Assignee: MITSUBISHI HEAVY INDUSTRIES, LTD., Tokyo (JP)

(21) Appl. No.: 18/879,460

(22) PCT Filed: Feb. 16, 2023
(86) PCT No.: PCT/JP2023/005528

§ 371 Date: Dec. 27, 2024

(30) Foreign Application Priority Data
Jul. 1, 2022 (JP) 2022-107146

(51) Int. Cl. H05K 7/20; H05K 1/02

(52) U.S. Cl. CPC H05K 7/20809; H05K 1/0203; H05K 2201/064

(57) ABSTRACT

A cooling device includes a heating unit having a storage space in which a liquid-phase refrigerant is stored, thermally connected to a heat generation body, and having a heat transfer surface that transfers heat of the heat generation body to the refrigerant; a refrigerant discharge pipe configured to be connected to the heating unit, and discharge the refrigerant from the storage space; a cooling unit configured to be connected to the refrigerant discharge pipe, and cool the refrigerant discharged from the heating unit; a refrigerant supply pipe configured to connect the cooling unit and the heating unit, and supply the refrigerant cooled by the cooling unit to the heating unit; and a negative pressure adjustment unit configured to make the storage space negative pressure, and adjust the internal pressure of the storage space.

### TECHNICAL FIELD

The present disclosure relates to a cooling device.

Priority is claimed on Japanese Patent Application No. 2022-107146, filed Jul. 1, 2022, the content of which is incorporated herein by reference.

### BACKGROUND ART

Patent Document 1 discloses a cooling system that directly cools an electronic device having a heat generation body by immersing the electronic device in a liquid refrigerant. The refrigerant used in the cooling system has fluorocarbon as a main component.

### CITATION LIST

### Patent Document

Patent Document 1: PCT International Publication NO. WO2016/075838A

### SUMMARY OF INVENTION

### Technical Problem

A refrigerant containing fluorocarbon as a main component is often employed in a case where a chip such as a GPU or a CPU in a server is locally cooled. However, these refrigerants have a problem in that they have a large global warming potential (GWP).

The present disclosure has been made in order to solve the above-described problem, and an object of the present disclosure is to provide a cooling device capable of sufficiently securing cooling performance while using a refrigerant having a small GWP.

### Solution to Problem

In order to solve the above-described problem, a cooling device according to the present disclosure includes: a heating unit having a storage space in which a liquid-phase refrigerant is stored, thermally connected to a heat generation body, and having a heat transfer surface which transfers heat of the heat generation body to the refrigerant; a refrigerant discharge pipe configured to be connected to the heating unit, and discharge the refrigerant from the storage space; a cooling unit configured to be connected to the refrigerant discharge pipe, and cool the refrigerant discharged from the heating unit; a refrigerant supply pipe configured to connect the cooling unit and the heating unit, and supply the refrigerant cooled by the cooling unit to the heating unit; and a negative pressure adjustment unit configured to make the storage space negative pressure, and adjust the internal pressure of the storage space.

### Advantageous Effects of Invention

According to the cooling device of the present disclosure, it is possible to sufficiently secure cooling performance while using the refrigerant having a smaller GWP.

### BRIEF DESCRIPTION OF DRAWINGS

FIG. 1 A schematic view showing the configuration of a cooling device according to a first embodiment of the present disclosure.

FIG. 2 A cross-sectional view of a heating unit according to the first embodiment of the present disclosure.

FIG. 3 A schematic view showing the configuration of a cooling device according to a second embodiment of the present disclosure.

FIG. 4 A schematic view showing the configuration of a cooling device according to a first modification example of the second embodiment of the present disclosure.

FIG. 5 A schematic view showing the configuration of a cooling device according to a second modification example of the second embodiment of the present disclosure.

FIG. 6 A perspective view showing an inside of a heating unit according to a third embodiment of the present disclosure.

FIG. 7 An enlarged view of a fin according to a first modification example of the third embodiment of the present disclosure.

FIG. 8 A perspective view showing an inside of a heating unit according to a second modification example of the third embodiment of the present disclosure.

FIG. 9 A schematic view showing the configuration of a cooling device according to a fourth embodiment of the present disclosure.

FIG. 10 A schematic view showing the configuration of a cooling device according to a modification example of the fourth embodiment of the present disclosure.

### DESCRIPTION OF EMBODIMENTS

### First Embodiment

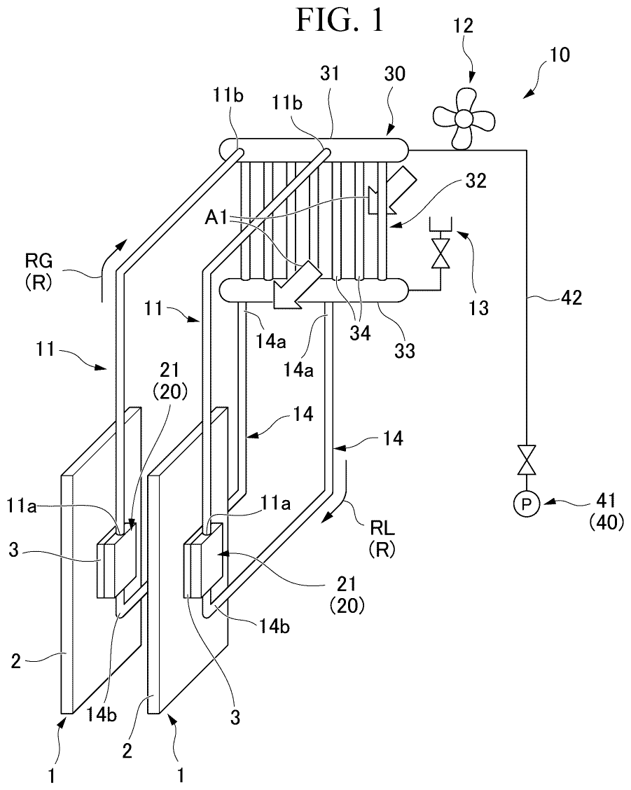

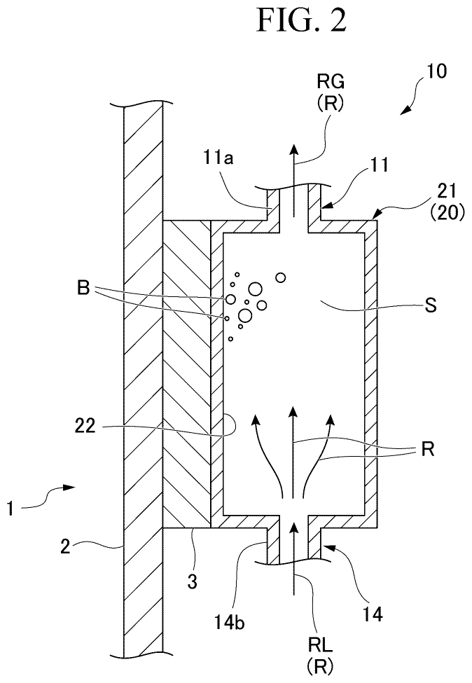

Hereinafter, a cooling device 10 according to a first embodiment of the present disclosure will be described with reference to FIGS. 1 and 2.

As shown in FIG. 1, the cooling device 10 is used for cooling an electronic device that performs high-speed calculation. In the present embodiment, the cooling device 10 is used for a server 1 in a data center. A plurality of servers 1 are provided.

The server 1 has a print substrate on which electronic components such as a chip of a CPU or a GPU, and the like are installed. Since the CPU or the GPU is a component that is responsible for high-speed calculation processing, a high load is applied. Therefore, the CPU or the GPU generates heat at a higher temperature than other portions of the server 1.

Hereinafter, the print substrate of the server 1 may be simply referred to as a “substrate 2”, and the chip of the CPU or the GPU may be referred to as a “heat generation body 3”.

The substrate 2 is formed in a rectangular plate shape. The substrate 2 is vertically disposed to extend in an up-down direction. In the present embodiment, a plurality of substrates 2 are provided.

The heat generation body 3 is installed on each substrate 2 one by one. The heat generation body 3 is installed to be attached to a surface of the substrate 2.

Therefore, in the present embodiment, the heat generation body 3 is vertically disposed to extend in the up-down direction as the substrate 2.

### Configuration of Cooling Device

Next, a configuration of the cooling device 10 will be described.

The cooling device 10 locally cools a chip (heat generation body 3) of the CPU, the GPU, or the like installed on the substrate 2. As shown in FIG. 1, the cooling device 10 includes a heating unit 20, a refrigerant discharge pipe 11, a cooling unit 30, a fan 12, a refrigerant filling unit 13, a refrigerant supply pipe 14, and a negative pressure adjustment unit 40.

### Heating Unit

The heating unit 20 of the present embodiment is a jacket 21 having a rectangular plate shape that is installed on a surface of the heat generation body 3 opposite to the substrate 2. The heating unit 20 is installed for each heat generation body 3 one by one. As shown in FIG. 2, the heating unit 20 has a storage space S in which a liquid-phase refrigerant R is stored. The heating unit 20 is thermally connected to the heat generation body 3. The heating unit 20 has a heat transfer surface 22 that transfers heat of the heat generation body 3 to the refrigerant R. The heat transfer surface 22 is a surface of an inner peripheral surface of the heating unit 20, which is relatively close to the heat generation body 3. In the present embodiment, the heating unit 20 is vertically disposed to extend in the up-down direction as the substrate 2. Therefore, the heat transfer surface 22 extends along a vertical plane.

The heat of the heat generation body 3 is transferred to the heating unit 20. Further, the heat of the heat generation body 3 is transferred to the liquid-phase refrigerant R in the storage space S via the heat transfer surface 22. Therefore, the liquid-phase refrigerant R in the storage space S is heated. As a result, the liquid-phase refrigerant R in the storage space S expands, and the density decreases. In the present embodiment, the liquid-phase refrigerant R in the storage space S is boiled and changed to a gas phase.

The refrigerant R is a low-GWP refrigerant having a smaller GWP than a fluorine-based refrigerant. The refrigerant (low-GWP refrigerant) R of the present embodiment is water. In addition to water, examples of the low-GWP refrigerant include hydrofluoroolefin (HFO). In addition, hereinafter, the liquid-phase refrigerant R may be simply referred to as a “liquid-phase refrigerant RL”, and the gas-phase refrigerant R may be simply referred to as a “gas-phase refrigerant RG”.

The heating unit 20 is provided with the refrigerant discharge pipe 11 that discharges the refrigerant R from the storage space S.

### Refrigerant Discharge Pipe

As shown in FIG. 1, a first end 11a of the refrigerant discharge pipe 11 is connected to an upper portion of the heating unit 20. A second end 11b of the refrigerant discharge pipe 11 is connected to the cooling unit 30. The refrigerant discharge pipe 11 guides the refrigerant R heated by the heating unit 20 to the cooling unit 30. The refrigerant discharge pipe 11 is provided in each heating unit 20 one by one.

### Cooling Unit

The cooling unit 30 cools the refrigerant R discharged from the heating unit 20. The cooling unit 30 of the present embodiment is an air-cooled heat exchanger. The cooling unit 30 has an upstream header 31, a tube bundle 32, and a downstream header 33.

The upstream header 31 is supplied with the refrigerant R heated by the heating unit 20. The upstream header 31 is a manifold header.

The tube bundle 32 has a plurality of fin tubes 34. Each fin tube 34 is connected to the upstream header 31. The refrigerant R is supplied to each fin tube 34 from the upstream header 31. In the drawings, a fin portion of the fin tube 34 is omitted.

The downstream header 33 is connected to the tube bundle 32. The downstream header 33 is a manifold header as the upstream header 31. In the downstream header 33, the refrigerant R passed through each fin tube 34 joins together.

### Fan

The fan 12 is installed near the tube bundle 32. The fan 12 blows air toward the tube bundle 32 and supplies an air A1 to each fin tube 34. As a result, the refrigerant R passing through the fin tubes 34 is cooled. In the present embodiment, the gas-phase refrigerant RG is condensed and changed to the liquid-phase refrigerant RL.

### Refrigerant Filling Unit

The downstream header 33 is provided with a refrigerant filling unit 13. The refrigerant filling unit 13 fills the refrigerant R in the cooling system. The refrigerant filling unit 13 fills the inside of the cooling device 10 with the liquid-phase refrigerant RL having a desired liquid amount.

### Refrigerant Supply Pipe

In addition, the downstream header 33 is provided with the refrigerant supply pipe 14. The refrigerant supply pipe 14 connects the cooling unit 30 and the heating unit 20. In the present embodiment, a first end 14a of the refrigerant supply pipe 14 is connected to the downstream header 33 of the cooling unit 30, and a second end 14b of the refrigerant supply pipe 14 is connected to a lower portion of the heating unit 20.

The refrigerant supply pipe 14 supplies the refrigerant R cooled by the cooling unit 30 to the heating unit 20. The refrigerant supply pipe 14 is provided for each heating unit 20 one by one.

### Negative Pressure Adjustment Unit

In addition, the negative pressure adjustment unit 40 is connected to the upstream header 31 via a vacuum drawing line 42. The negative pressure adjustment unit 40 of the present embodiment is a vacuum pump 41. The negative pressure adjustment unit 40 performs vacuum drawing in the cooling device 10 to make the storage space S negative pressure. Further, the negative pressure adjustment unit 40 can adjust the internal pressure of the storage space S.

### Circulation of Refrigerant

Next, circulation of the refrigerant R in the cooling device 10 will be described.

First, the vacuum pump 41 is operated to perform vacuum drawing in the cooling device 10. As a result, the inside of the cooling device 10 including the storage space S is in a negative pressure. Therefore, a boiling point of the refrigerant R in the cooling device 10 is lowered. As a result, the refrigerant R is likely to change from the liquid phase to the gas phase.

In addition, the heat of the heat generation body 3 is transferred to the heating unit 20. The heat transfer surface 22 in the heating unit 20 transfers the heat of the heat generation body 3 to the liquid-phase refrigerant RL in the storage space S. Accordingly, the heat generation body 3 is cooled. On the other hand, the liquid-phase refrigerant RL in the storage space S is heated and expands. In the present embodiment, the liquid-phase refrigerant RL is boiled by the heat of the heat generation body 3 and is changed to the gas-phase refrigerant RG. Since the density of the gas-phase refrigerant RG is smaller than the density of the liquid-phase refrigerant RL, the gas-phase refrigerant RG flows upward. The gas-phase refrigerant RG flows from the heating unit 20 to the cooling unit 30 through the refrigerant discharge pipe 11.

The gas-phase refrigerant RG moves from the upstream header 31 to the fin tubes 34 and from the fin tubes 34 to the downstream header 33. The gas-phase refrigerant RG is cooled by performing heat exchange with the air A1 supplied from the fan 12 in the fin tubes 34. As a result, the gas-phase refrigerant RG is condensed and is changed to the liquid-phase refrigerant RL by the time the gas-phase refrigerant RG reaches the downstream header 33.

The liquid-phase refrigerant RL returns to the heating unit 20 from the downstream header 33 through the refrigerant supply pipe 14. The liquid-phase refrigerant RL returned to the heating unit 20 performs heat exchange with the heat generation body 3 again in the heating unit 20. In this way, the refrigerant R circulates in the cooling device 10.

### Effects

The cooling device 10 according to the present embodiment can exhibit the following effects.

In the present embodiment, the heating unit 20 has the storage space S in which the liquid-phase refrigerant R is stored and is thermally connected to the heat generation body 3. Further, the heating unit 20 includes the heat transfer surface 22 that transfers heat of the heat generation body 3 to the refrigerant R. In addition, the negative pressure adjustment unit 40 makes the storage space S negative pressure and can adjust the internal pressure of the storage space S.

According to the present embodiment, the heat generation body 3 is cooled by heat exchange with the refrigerant R in the storage space S via the heating unit 20. On the other hand, the refrigerant R in the storage space S is heated by the heat of the heat generation body 3. By making the storage space S negative pressure, the boiling point of the refrigerant R is lowered, and the refrigerant R is likely to expand. When the refrigerant R expands, the density of the refrigerant R decreases. As a result, the refrigerant R is likely to circulate in the cooling device 10. Therefore, a refrigerant having a small GWP but having a high boiling point and thus being unsuitable for circulating in a cycle can be used in the cooling device 10. Therefore, the refrigerant R having a small GWP can be used in the cooling device 10. Therefore, it is possible to sufficiently secure cooling performance while using the refrigerant (low GWP refrigerant) R having a smaller GWP than the fluorine-based refrigerant. As a result, it is possible to reduce the influence on global warming.

In addition, for example, during maintenance of the cooling device 10, a degree of negative pressure in the storage space S can be adjusted according to the environment of the cooling device 10 by operating the negative pressure adjustment unit 40. For example, the degree of the negative pressure of the storage space S can be adjusted according to an ambient temperature of a place where the cooling device 10 is installed or a load of the heat generation body 3.

In addition, in the present embodiment, the refrigerant discharge pipe 11 is connected to the upper portion of the heating unit 20. The refrigerant supply pipe 14 is connected to the lower portion of the heating unit 20. The heat transfer surface 22 extends along a vertical plane.

According to the present embodiment, in the heating unit 20, the liquid-phase refrigerant RL flows upward. As a result, even if where an air bubble B is generated in the heating unit 20 (refer to FIG. 2), the air bubble B is likely to flow into the upper refrigerant discharge pipe 11. Therefore, the air bubble B is likely to escape to the cooling unit 30 through the refrigerant discharge pipe 11. As a result, the retention of the air bubbles B in the heating unit 20 and the formation of a vapor film on the heat transfer surface 22 are suppressed. Therefore, the refrigerant R is smoothly circulated, and the heat exchange between the heat generation body 3 and the refrigerant R is smoothly performed.

### Second Embodiment

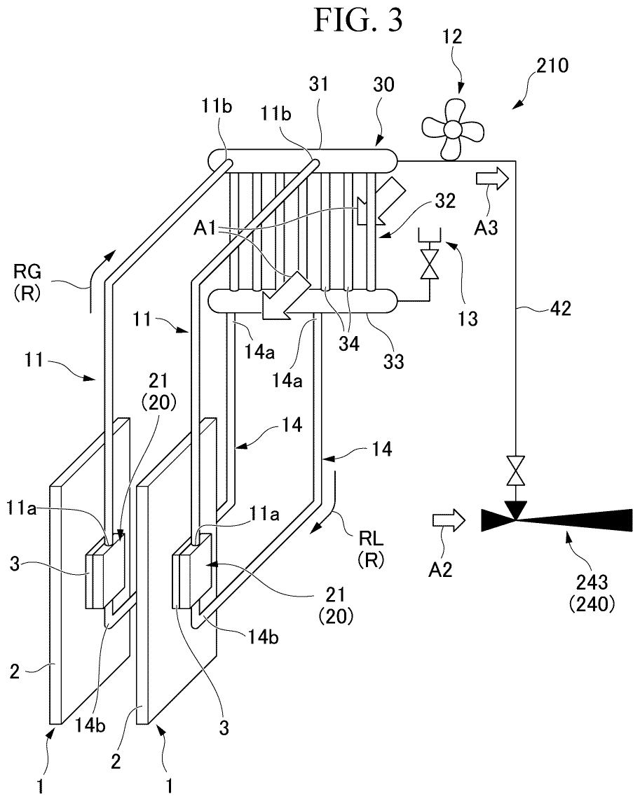

Next, a cooling device 210 according to a second embodiment of the present disclosure will be described with reference to FIG. 3. The same configurations as those in the first embodiment described above are designated by the same names and the same reference signs, and descriptions thereof will be appropriately omitted.

As shown in FIG. 3, in the present embodiment, a negative pressure adjustment unit 240 is an ejector 243. The ejector 243 drives a flow of air supplied from the outside of the cooling device 210 as a driving current A2. The ejector 243 is connected to the upstream header 31 of the cooling unit 30 by the vacuum drawing line 42. The ejector 243 draws a gas A3 in the cooling device 210 by the driving current A2 and makes the inside of the cooling device 210 including the storage space S negative pressure.

### Effects

According to the cooling device 210 of the present embodiment, the following effects are exhibited.

In the present embodiment, the negative pressure adjustment unit 240 is the ejector 243.

Accordingly, the cooling device 210 can drive the ejector 243 using, for example, air discharged from a factory or the like as the driving current A2.

Accordingly, the cooling device 210 can perform vacuum drawing inside the device including the storage space S with less power consumption than in a case where the negative pressure adjustment unit 240 is a vacuum pump.

### First Modification Example of Second Embodiment

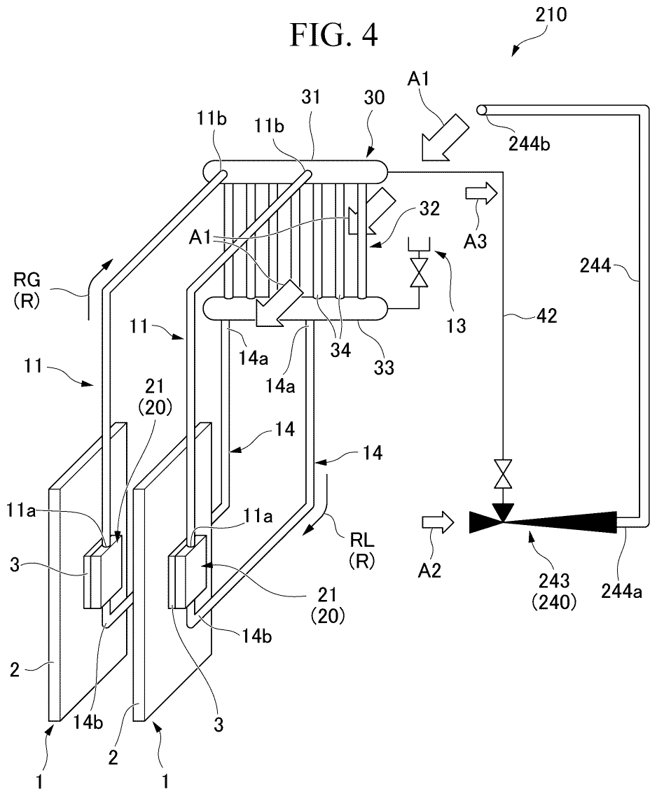

Next, a first modification example of the second embodiment will be described with reference to FIG. 4.

As shown in FIG. 4, in the present modification example, the cooling device 210 further includes a blowing line 244. A first end 244a of the blowing line 244 is connected to a discharge port of the ejector 243. A second end 244b of the blowing line 244 is disposed at a position facing the tube bundle 32 of the cooling unit 30. The blowing line 244 supplies the air A1 discharged from the ejector 243 to the cooling unit 30. The cooling unit 30 cools the refrigerant R by performing heat exchange between the air A1 discharged from the ejector 243 and the refrigerant R.

Accordingly, the cooling device 210 can cool the refrigerant R in the cooling unit 30 with the air A1 discharged from the ejector 243. Therefore, it is possible to reduce the power consumption of the cooling device 210 as compared with a case where a blower such as the fan 12 is used for supplying the air Al to the cooling unit 30.

### Second Modification Example of Second Embodiment

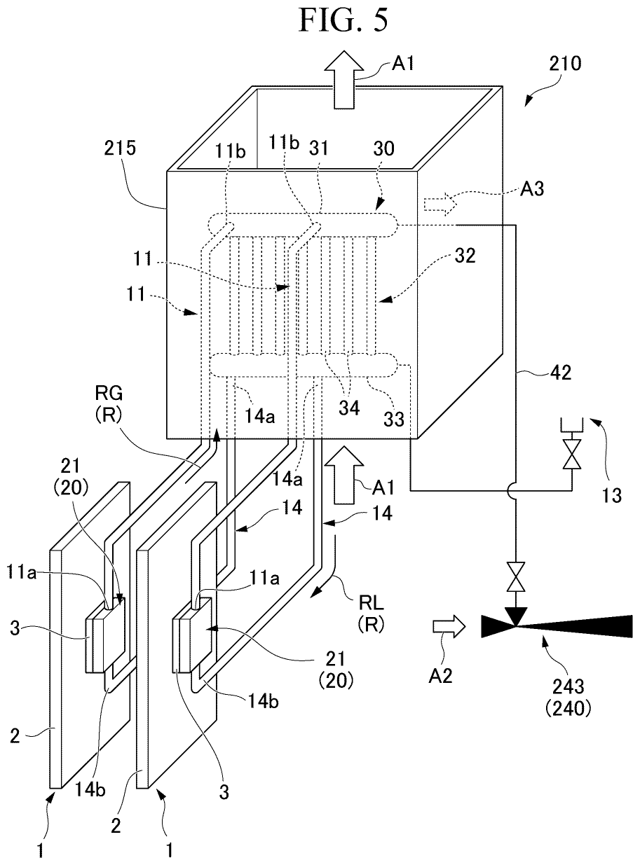

Next, a second modification example of the second embodiment will be described with reference to FIG. 5.

As shown in FIG. 5, in the present modification example, the cooling device 210 includes an outer tube 215 that surrounds the cooling unit 30 and is open in the up-down direction. The outer tube 215 is formed in a quadrangular tubular shape. The shape of the outer tube 215 can be appropriately changed. For example, the outer tube 215 may be formed in a cylindrical shape.

According to the present modification example, the air A1 around the cooling unit 30 heated by performing heat exchange with the refrigerant R inside the cooling unit 30 rises, and a flow that blows upward into the outer tube 215 is generated. As a result, fresh air A1 for cooling the refrigerant R is continuously supplied to the cooling unit 30. Therefore, it is not necessary to provide a blower such as the fan 12 in order to supply the air A1 to the cooling unit 30. As a result, an increase in size of the cooling device 210 is suppressed. In addition, it is possible to reduce the power consumption of the cooling device 210.

### Third Embodiment

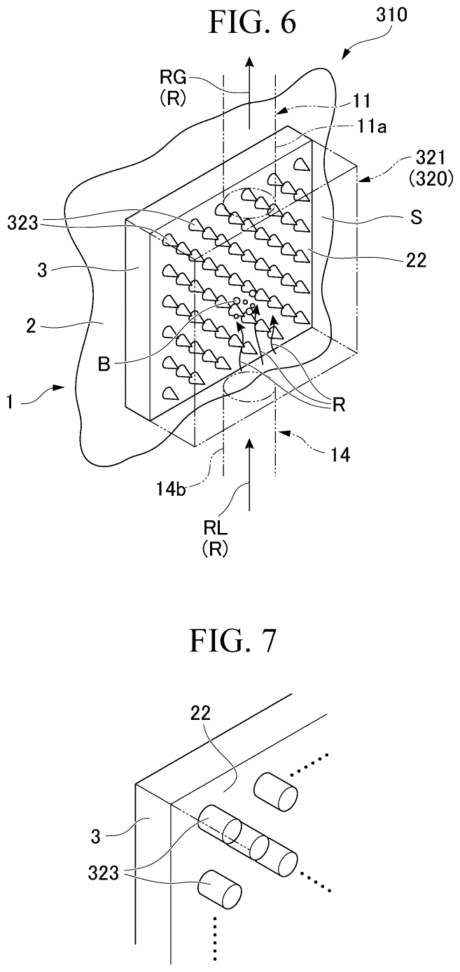

Hereinafter, a cooling device 310 according to a third embodiment of the present disclosure will be described with reference to FIG. 6. The same configurations as those in the first embodiment described above are designated by the same names and the same reference signs, and descriptions thereof will be appropriately omitted.

As shown in FIG. 6, in the present embodiment, the heating unit 320 (jacket 321) has a plurality of fins 323 that rise from the heat transfer surface 22 in the storage space S. The fins 323 extend vertically from the heat transfer surface 22. The fins 323 are formed in a conical shape that tapers away from the heat transfer surface 22. The plurality of fins 323 are arranged in a quadrangular lattice shape as viewed from a perpendicular direction of the heat transfer surface 22.

### Effects

According to the cooling device 310 of the present embodiment, the following effects are exhibited.

In the present embodiment, the heating unit 320 has a plurality of fins 323 that rise from the heat transfer surface 22.

As a result, an area of the heat transfer surface 22 is increased. Therefore, an apparent heat flux in the heating unit 320 can be reduced. In addition, the detachment of the air bubbles B generated on the heat transfer surface 22 is promoted. Therefore, the plurality of air bubbles B are suppressed from being integrated on the heat transfer surface 22. Further, in the heating unit 320, the refrigerant R flows in a meandering manner, and mixing of the refrigerant R is promoted. As a result, the formation of the vapor film on the heat transfer surface 22 is suppressed. Therefore, a limit heat flux in the heating unit 320 increases, and a limit value of heat transport increases.

### First Modification Example of Third Embodiment

Next, a first modification example of the third embodiment will be described with reference to FIG. 7.

As shown in FIG. 7, in the present modification example, the fins 323 are formed in a columnar pin-like shape.

As a result, the area of the heat transfer surface 22 is further increased. Therefore, the apparent heat flux in the heating unit 320 can be further reduced.

### Second Modification Example of Third Embodiment

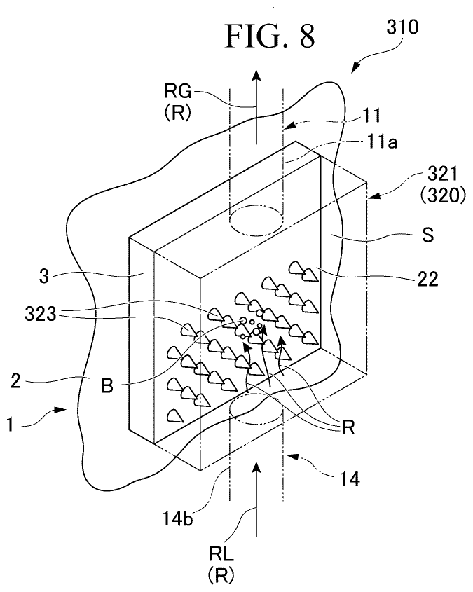

Next, a second modification example of the third embodiment will be described with reference to FIG. 8.

As shown in FIG. 8, in the present modification example, the fins 323 are formed only in a region of the heat transfer surface 22 on a refrigerant supply pipe 14 side. For example, the fins 323 are formed on half of the heat transfer surface 22 on the refrigerant supply pipe 14 side.

For example, the refrigerant R may be present in the liquid phase in a region of the heat transfer surface 22 on the refrigerant supply pipe 14 side and may be present in the gas phase on a refrigerant discharge pipe 11 side. According to the present modification example, the cooling device 310 can mix the liquid-phase refrigerant R stored in the region on the refrigerant supply pipe 14 side in the refrigerant R in the heating unit 20 by the fins 323. As a result, the cooling device 310 can stabilize the flow of the refrigerant R. Therefore, the cooling efficiency of the cooling device 310 can be improved.

### Fourth Embodiment

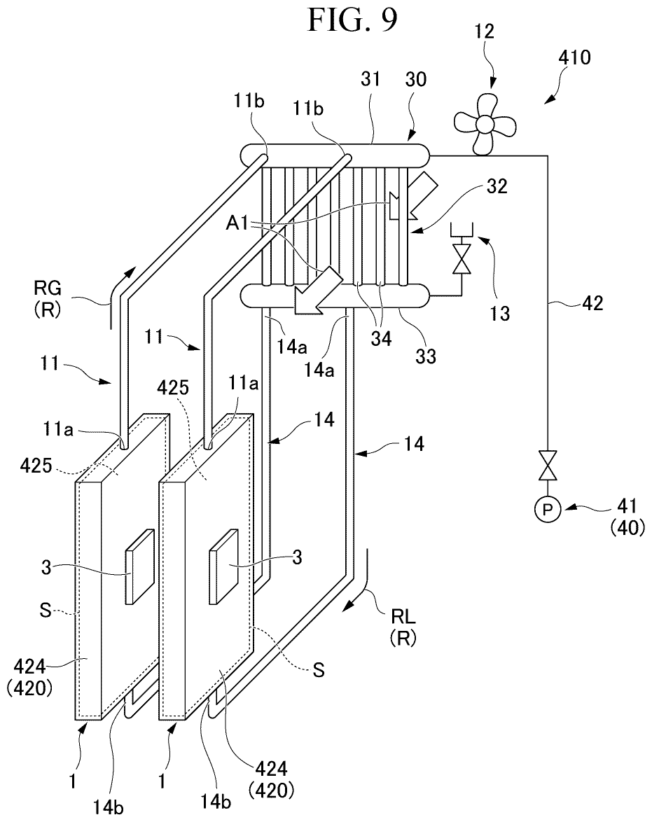

Hereinafter, a cooling device 410 according to a fourth embodiment of the present disclosure will be described with reference to FIG. 9. The same configurations as those in the first embodiment described above are designated by the same names and the same reference signs, and descriptions thereof will be appropriately omitted.

As shown in FIG. 9, in the present embodiment, a heating unit 420 of the cooling device 410 is a substrate 424 on which the electronic component is installed. The storage space S is formed inside the substrate 424. The storage space S is formed, for example, over the entire region of the substrate 424. In addition, the substrate 424 has a heat transfer surface 425 inside. The heat transfer surface 425 transfers the heat of the heat generation body 3 to the refrigerant R in the storage space S.

As a result, a distance through which the refrigerant R flows in the heating unit 420 can be increased. Therefore, the evaporation of the refrigerant R is promoted. Therefore, the refrigerant R is more likely to circulate in the cooling device 410. In addition, the cooling device 410 can dissipate the heat of the heat generation body 3 to the substrate 424. Therefore, the cooling efficiency of the cooling device 410 can be improved.

### Modification Example of Fourth Embodiment

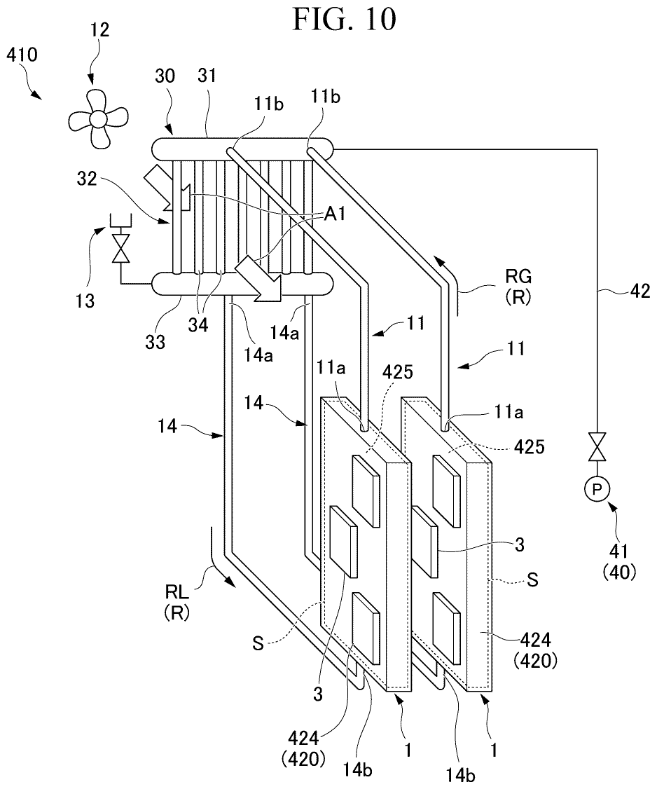

Next, a modification example of the fourth embodiment will be described with reference to FIG. 10.

As shown in FIG. 10, in the present modification example, a plurality of heat generation bodies 3 are thermally connected to the heating unit 420.

As a result, the cooling device 410 can equalize the temperatures of the plurality of heat generation bodies 3 in one heating unit 420. Therefore, it is easy to control each heat generation body 3.

### Other Embodiments

The embodiments of the present disclosure have been described above in detail with reference to the drawings. However, specific configurations are not limited to the embodiments, and include a design modification or the like within a scope which does not depart from the gist of the present disclosure.

In the above-described embodiments, a plurality of substrates 2 and 424 are provided, but the present invention is not limited thereto. For example, only one of the substrates 2 and 424 may be provided. The number of substrates 2 and 424 can be appropriately changed according to a required load.

In the above-described embodiments, the heating units 20, 320, and 420 evaporate the refrigerant R to change the refrigerant R from the liquid phase to the gas phase, but the present invention is not limited thereto. In the heating units 20, 320, and 420, the refrigerant R may remain in the liquid phase without evaporating as long as the refrigerant R expands.

In the above-described embodiments, the cooling unit 30 is the air-cooled heat exchanger, but the present invention is not limited thereto.

### Appendixes

The cooling devices 10, 210, 310, and 410 described in each embodiment are grasped, for example, as follows.
(1) The cooling devices 10, 210, 310, and 410 according to a first aspect include the heating units 20, 320, and 420 having the storage space S in which the liquid-phase refrigerant R is stored, thermally connected to the heat generation body 3, and having the heat transfer surfaces 22 and 425 which transfer the heat of the heat generation body 3 to the refrigerant R, the refrigerant discharge pipe 11 configured to be connected to the heating units 20, 320, and 420, and discharge the refrigerant R from the storage space S, the cooling unit 30 configured to be connected to the refrigerant discharge pipe 11, and cool the refrigerant R discharged from the heating units 20, 320, and 420, the refrigerant supply pipe 14 configured to connect the cooling unit 30 and the heating units 20, 320, and 420, and supply the refrigerant R cooled by the cooling unit 30 to the heating units 20, 320, and 420, and the negative pressure adjustment units 40 and 240 configured to make the storage space S negative pressure, and adjust the internal pressure of the storage space S.

According to the present aspect, the heat generation body 3 is cooled by heat exchange with the refrigerant R in the storage space S via the heating units 20, 320, and 420. On the other hand, the refrigerant R in the storage space S is heated by the heat of the heat generation body 3. By making the storage space S negative pressure, the boiling point of the refrigerant R is lowered, and the refrigerant R is likely to expand. When the refrigerant R expands, the density of the refrigerant R decreases. As a result, the refrigerant R is likely to circulate in the cooling devices 10, 210, 310, and 410. Therefore, the refrigerant having a small GWP but having a high boiling point and thus being unsuitable for circulating in the cycle can be used in the cooling devices 10, 210, 310, and 410. Therefore, the refrigerant R having a small GWP can be used in the cooling devices 10, 210, 310, and 410.
(2) The cooling devices 10, 210, 310, and 410 of a second aspect are the cooling devices 10, 210, 310, and 410 of (1), in which the refrigerant discharge pipe 11 may be connected to the upper portions of the heating units 20, 320, and 420, the refrigerant supply pipe 14 may be connected to the lower portions of the heating units 20, 320, and 420, and the heat transfer surfaces 22 and 425 may extend along the vertical plane.

As a result, even if the air bubbles B are generated in the heating units 20, 320, and 420, the air bubbles B are likely to escape to the cooling unit 30 through the refrigerant discharge pipe 11.
(3) The cooling device 210 of a third aspect is the cooling device 210 of (1) or (2), in which the negative pressure adjustment unit 240 may be the ejector 243.

Accordingly, the cooling device 210 can drive the ejector 243 using, for example, air discharged from a factory or the like as the driving current A2.
(4) The cooling device 210 of a fourth aspect is the cooling device 210 of (3), and may further include the blowing line 244 configured to supply the air Al discharged from the ejector 243 to the cooling unit 30, in which the cooling unit 30 may cool the refrigerant R by performing heat exchange between the air Al discharged from the ejector 243 and the refrigerant R.

Accordingly, the cooling device 210 can cool the refrigerant R in the cooling unit 30 with the air A1 discharged from the ejector 243.
(5) The cooling device 210 of a fifth aspect is the cooling device 210 of any one of (1) to (4), and may further include the outer tube 215 configured to surround the cooling unit 30 and to be open in the up-down direction.

As a result, the air A1 around the cooling unit 30 heated by performing heat exchange with the refrigerant R inside the cooling unit 30 rises, and the flow blowing upward in the outer tube 215 is generated. As a result, fresh air A1 for cooling the refrigerant R is continuously supplied to the cooling unit 30.
(6) The cooling device 310 according to a sixth aspect is the cooling device 310 according to any one of (1) to (5), in which the heating unit 320 may include a plurality of fins 323 that rise from the heat transfer surface 22.

As a result, an area of the heat transfer surface 22 is increased. In addition, the detachment of the air bubbles B generated on the heat transfer surfaces 22 and 425 is promoted. Further, in the heating unit 320, the refrigerant R flows in a meandering manner, and mixing of the refrigerant R is promoted.
(7) The cooling device 310 according to a seventh aspect is the cooling device 310 according to (6), in which the fins 323 may be formed only in the region in the heat transfer surface 22 on the refrigerant supply pipe 14 side.

For example, the refrigerant R may be present in the liquid phase in a region of the heat transfer surface 22 on the refrigerant supply pipe 14 side and may be present in the gas phase on a refrigerant discharge pipe 11 side. According to the present aspect, the cooling device 310 can mix the liquid-phase refrigerant R stored in the region on the refrigerant supply pipe 14 side in the refrigerant R in the heating unit 20 by the fins 323.
(8) The cooling device 410 of an eighth aspect is the cooling device 410 of any one of (1) to (7), in which the heating unit 420 may be the substrate 424 on which the electronic component is installed, and the storage space S may be formed inside the substrate 424.

As a result, a distance through which the refrigerant R flows in the heating unit 420 can be increased. Therefore, the evaporation of the refrigerant R is promoted.
(9) The cooling device 410 of a ninth aspect is the cooling device 410 of any one of (1) to (8), in which a plurality of the heat generation bodies 3 may be thermally connected to the heating unit 420.

As a result, the cooling device 410 can equalize the temperatures of the plurality of heat generation bodies 3.
(10) The cooling devices 10, 210, 310, and 410 of a tenth aspect are the cooling devices 10, 210, 310, and 410 of any one of (1) to (9), in which the refrigerant R may be the low-GWP refrigerant having a smaller GWP than the GWP of a fluorine-based refrigerant.

Examples of the low-GWP refrigerant include water, hydrofluoroolefin (HFO), and the like.

### INDUSTRIAL APPLICABILITY

According to the cooling device of the present disclosure, it is possible to sufficiently secure cooling performance while using the refrigerant having a smaller GWP.

### REFERENCE SIGNS LIST

1 Server
2 Substrate
3 Heat generation body
10 Cooling device
11 Refrigerant discharge pipe
11a First end
11b Second end
12 Fan
13 Refrigerant filling unit
14 Refrigerant supply pipe
14a First end
14b Second end
20 Heating unit
21 Jacket
22 Heat transfer surface
30 Cooling unit
31 Upstream header
32 Tube bundle
33 Downstream header
34 Fin tube
40 Negative pressure adjustment unit
41 Vacuum pump
42 Vacuum drawing line
210 Cooling device
215 Outer tube
240 Negative pressure adjustment unit
243 Ejector
244 Blowing line
244a First end
244b Second end
310 Cooling device
320 Heating unit
321 Jacket
323 Fin
410 Cooling device
420 Heating unit
424 Substrate
425 Heat transfer surface
A1 Air
A2 Driving current
A3 Gas
R Refrigerant
RG Gas-phase refrigerant
RL Liquid-phase refrigerant
S Storage space

1. A cooling device comprising:
a heating unit having a storage space in which a liquid-phase refrigerant is stored, thermally connected to a heat generation body, and having a heat transfer surface which transfers heat of the heat generation body to the refrigerant;
a refrigerant discharge pipe configured to be connected to the heating unit, and discharge the refrigerant from the storage space;
a cooling unit configured to be connected to the refrigerant discharge pipe, and cool the refrigerant discharged from the heating unit;
a refrigerant supply pipe configured to connect the cooling unit and the heating unit, and supply the refrigerant cooled by the cooling unit to the heating unit; and
a negative pressure adjustment unit configured to make the storage space negative pressure, and adjust an internal pressure of the storage space, wherein
the refrigerant discharge pipe is connected to an upper portion of the heating unit,
the refrigerant supply pipe is connected to a lower portion of the heating unit, and
the heat transfer surface extends along a vertical plane.

2. (canceled)

3. The cooling device according to claim 1, wherein the negative pressure adjustment unit is an ejector.

4. The cooling device according to claim 3, further comprising:
a blowing line configured to supply air discharged from the ejector to the cooling unit,
wherein the cooling unit cools the refrigerant by performing heat exchange between the air discharged from the ejector and the refrigerant.

5. The cooling device according to claim 1, further comprising:
an outer tube configured to surround the cooling unit and to be open in an up-down direction.

6. The cooling device according to claim 1, wherein the heating unit includes a plurality of fins that rise from the heat transfer surface.

7. The cooling device according to claim 6, wherein the fins are formed only in a region in the heat transfer surface on a refrigerant supply pipe side.

8. The cooling device according to claim 1, wherein the heating unit is a substrate on which an electronic component is installed, and the storage space is formed inside the substrate.

9. The cooling device according to claim 1, wherein a plurality of the heat generation bodies are thermally connected to the heating unit.

10. The cooling device according to claim 1, wherein the refrigerant is a low-GWP refrigerant having a smaller GWP than a GWP of a fluorine-based refrigerant.
